(19) United States
(12) Patent Application Publication
(10) Pub. No.: US 2010/0051970 A1
(43) Pub. Date: Mar. 4, 2010

(54) PLANARIZED LED WITH OPTICAL EXTRACTOR

(76) Inventors: Andrew J. Ouderkirk, Singapore (SG); Catherine A. Leatherdale, Woodbury, MN (US)

Correspondence Address: 3M INNOVATIVE PROPERTIES COMPANY, PO BOX 33427, ST. PAUL, MN, 55133-3427, US

(21) Appl. No.: 12/515,400

(22) PCT Filed: Nov. 15, 2007
(86) PCT No.: PCT/US07/84802

§ 371 Date: May 18, 2009

Related U.S. Application Data
(60) Provisional application No. 60/866,265, filed on Nov. 17, 2006.

(51) Int. Cl. H01L 33/00; H01L 21/30; H01L 21/50

(52) U.S. Cl. 257/88; 257/98; 438/29; 438/27; 257/E33.067; 257/E21.211; 257/E21.499

(57) ABSTRACT

A light emitting article is disclosed and includes a light emitting diode having an n-layer or p-layer with a first refractive index value. A planarizing layer having a refractive index value equal to or greater than the first refractive index value is disposed on the n-layer or p-layer, and a patterned electrode is disposed on the n-layer or p-layer. An extractor having a light input surface is optically coupled to the planarizing layer.

### RELATED APPLICATIONS

This application claims the benefit of U.S. Provisional Patent Application No. 60/866265, filed Nov. 17, 2006, the disclosure of which is incorporated by reference herein in its entirety.

### BACKGROUND

The present disclosure relates generally to high efficiency light emitting articles and methods of forming the same.

Light emitting diodes (LEDs) have the inherent potential to provide brightness, output, and operational lifetime that would compete with conventional light sources. However, the external efficiency of these devices is often poor because light within only a small range of angles can escape from the high refractive index semiconductor material forming the LED.

The efficiency of the LED can be increased by attaching a high refractive index optical element to the surface of the semiconductor material. A high refractive index optical element can increase the range of angles that light can escape from the surface of the semiconductor material. The optical element can be suitably shaped such that light efficiently escapes from the LED. However, the optical element needs to be optically coupled to the surface of the semiconductor material for efficient light extraction to occur. Electrodes on the surface of the semiconductor material can hinder the optical coupling of the optical element and the surface of the semiconductor material.

### SUMMARY

The present disclosure relates generally to high efficiency light emitting articles and methods of forming the same. In particular, the present disclosure relates to light emitting articles that have an electrode that is coplanar with the surface of the light emitting article. These coplanar electrodes facilitate optical coupling of the surface of the light emitting article with an optical element or extractor.

In one exemplary implementation, a light emitting article is disclosed and includes a light emitting diode having an n-layer or p-layer with a first refractive index value. A planarizing layer having a refractive index value equal to or greater than the first refractive index value is disposed on the n-layer or p-layer, and a patterned electrode is disposed on the n-layer or p-layer. An extractor having a light input surface is optically coupled to the planarizing layer.

In another exemplary implementation, an array of light emitting articles includes a plurality of light emitting diodes optically coupled to a plurality of extractors. Each light emitting diode has an n-layer or p-layer having a first refractive index value, a planarizing layer having a refractive index value equal to or greater than the first refractive indexvalue and disposed on the n-layer or p-layer, and a patterned electrode disposed on the n-layer or p-layer. Each extractor has a light input surface optically coupled to a corresponding planarizing layer.

In a further exemplary implementation, a method of forming a light emitting article includes providing a light emitting diode having an n-layer or p-layer with a first refractive index value, a planarizing layer having a refractive index value equal to or greater than the first refractive index value and disposed on the n-layer or p-layer, and optically coupling a light input surface of an extractor to the planarizing layer. A patterned electrode is disposed on the n-layer or p-layer.

In a further exemplary implementation, a method of forming an array of light emitting articles includes providing an array light emitting diodes where each light emitting diode includes an n-layer or p-layer having a first refractive index value, a planarizing layer having a refractive index value equal to or greater than the first refractive index value and disposed on the n-layer or p-layer and optically coupling an array of extractor light input surfaces to the array of light emitting diodes planarizing surfaces. A patterned electrode is disposed on the n-layer or p-layer.

These and other aspects of the methods and articles according to the subject disclosure will become readily apparent to those of ordinary skill in the art from the following detailed description together with the drawings.

### BRIEF DESCRIPTION OF THE DRAWINGS

The disclosure may be more completely understood in consideration of the following detailed description of various embodiments of the disclosure in connection with the accompanying drawings, in which:

FIG. 1 is a schematic cross-sectional side elevation view of an exemplary light emitting article;

FIGS. 2A-2C are illustrative electrode patterns;

FIG. 3 is a schematic cross-sectional side elevation view of an exemplary array of light emitting articles;

FIG. 4 is a block diagram illustrating steps in manufacturing a light emitting article; and

FIGS. 5A-5C are schematic cross-sectional side elevation views of a light emitting article made according to the steps shown in FIG. 4.

While the disclosure is amenable to various modifications and alternate forms, specifics thereof have been shown by way of example in the drawings and will be described in detail. It should be understood, however, that the intention is not to limit the disclosure to the particular embodiments described. On the contrary, the intention is to cover all modifications, equivalents, and alternatives falling within the spirit and scope of the disclosure. Sizes of various elements in the drawings are approximate and many not be to scale.

### DETAILED DESCRIPTION

The present disclosure relates generally to high efficiency light emitting articles and methods of forming the same. In particular, the present disclosure relates to light emitting articles that have an electrode that is coplanar with the surface of the light emitting die or diode. These coplanar electrodes facilitate optical coupling of the surface of the light emitting die or diode with an optical element or extractor. In many embodiments, the electrode is a patterned electrode in a planarizing layer of the light emitting die or diode to provide uniform current across the surface of the light emitting die or diode. This patterned electrode allows a large fraction of the surface of the light emitting die or diode to be unobstructed.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

The recitation of numerical ranges by endpoints includes all numbers subsumed within that range (e.g. 1 to 5 includes 1, 1.5, 2, 2.75, 3, 3.80, 4, and 5) and any range within that range.

As used in this specification and the appended claims, the singular forms “a”, “an”, and “the” encompass embodiments having plural referents, unless the content clearly dictates otherwise. As used in this specification and the appended claims, the term “or” is generally employed in its sense including “and/or” unless the content clearly dictates otherwise.

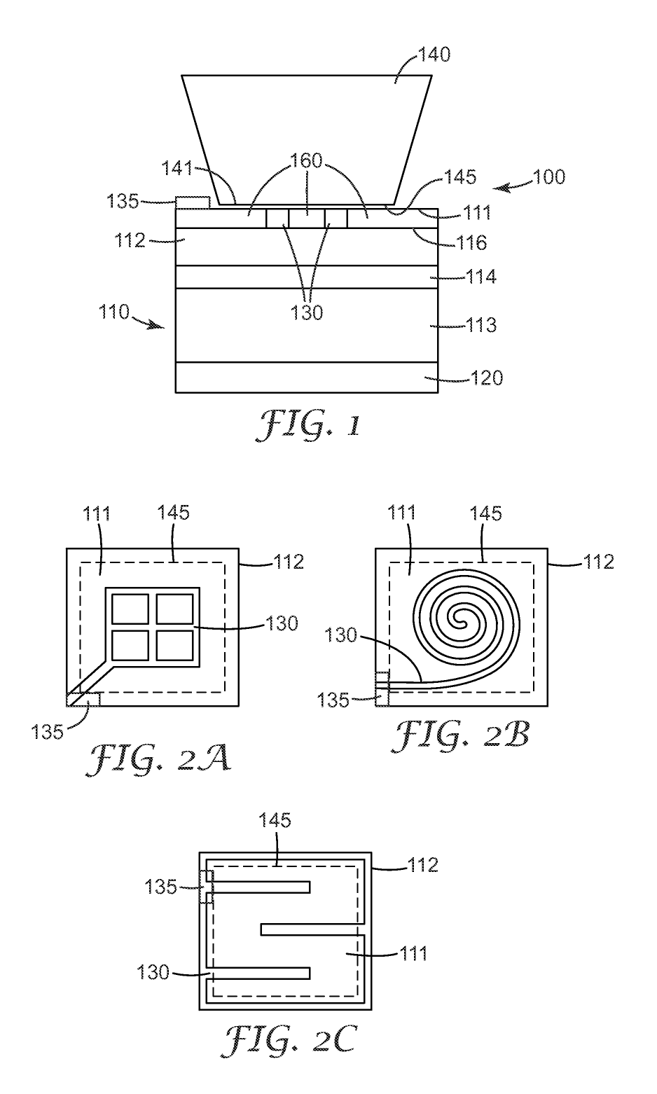

FIG. 1 is a schematic cross-sectional side elevation view of an exemplary light emitting article 100. The light emitting article 100 includes a light emitting die or diode 110 optically coupled to an optical element or extractor 140. The extractor 140 includes a light input surface 141 that is optically coupled to a light emitting surface 111 of the light emitting die or diode 110. The interface between the light input surface 141 and the light emitting surface 111 is a light emitting interface 145. The patterned electrode 130 is connected to one or more bonding pads 135 that are not within the light emitting interface 145.

The extractor 140 is considered optically coupled to the light emitting surface 111 when a minimum gap, defined by the distance between the two surfaces (141 and 111), is no greater than the evanescent wave. In many embodiments, the gap is an air gap having a thickness of less than 100 nm, or 50 nm, or 25 nm. In addition, the gap is substantially uniform over the area of contact between the light emitting surface 111 and the light input surface 141 (i.e. the light emitting interface 145) and that the light emitting surface 111 and the light input surface 141 both have a roughness of less than 20 nm, or less than 10 nm, or less than 5 nm. In case of a finite gap, optical coupling can be achieved or enhanced by adding an optically conducting layer between the light emitting surface 111 and the light input surface 141. In some embodiments, the optically conducting layer can be an optically conducting bonding layer to bond the light emitting surface 111 to the light input surface 141. The optically conducting bonding layer can be any suitable bonding agent that transmits light, including, for example, a transparent adhesive layer, inorganic thin films, fusable glass frit or other similar bonding agents. Additional examples, of bonded configurations are described, for example, in U.S. Patent Publication No. 2002/0030194. In other embodiments, the extractor is optically coupled to the light emitting surface in a non-bonded configuration as described in US 2006/0091784. Optically conducting layers can include index matching oils, and other liquids or gels with similar optical properties.

The light emitting die or diode 110 can include a plurality or stack of layers. The stack includes semiconductor layers and an active region capable of emitting light. The light emitting die or diode 110 includes a first semiconductor layer 113 of n-type conductivity (n-layer) and a second semiconductor layer 112 of p-type conductivity (p-layer). Semiconductor layers 113 and 112 are electrically coupled to active region 114. Active region 114 is, for example, a p-n junction associated with the interface of layers 113 and 112. Alternatively, active region or p-n junction 114 includes one or more semiconductor layers that are doped n-type or p-type or are undoped. Active region or p-n junction 114 can also include quantum wells. First contact or electrode (p-electrode) 130 and second contact or electrode (n-electrode) 120 are electrically coupled to semiconductor layers 112 and 113, respectively. Active region or p-n junction 114 emits light upon application of a suitable voltage across electrodes 130 and 120. In alternative implementations, the conductivity types of layers 113 and 112 are reversed. That is, layer 113 is a p-type layer, electrode 120 is a p-electrode, layer 112 is an n-type layer, and electrode 130 is an n-electrode. In another alternative implementation, the bonding pads for both the n-electrode and the p-electrode may be contacted from the light emitting side of the stack of semiconductor layers. The stack may also include buffer layers, cladding layers, bonding layers, conductive or non-conductive substrates such as is known in the art.

Semiconductor layers 113 and 112 and active region or n-p junction 114 are formed from Group III-V semiconductors, including but not limited to AlN, AlP, AlAs, AlSb, GaN, GaP, GaAs, GaSb, InN, InP, InAs, InSb, Group II-VI semiconductors including but not limited to ZnS, ZnSe, CdSe, CdTe, Group IV semiconductors including but not limited to Ge, Si, SiC, and mixtures or alloys thereof. These semiconductors have indices of refraction ranging from about 2.4 to about 4.1 at the typical emission wavelengths of light emitting articles in which they are present. For example, III-Nitride semiconductors such as GaN have refractive indices of about 2.4 at 500 nm, and III-Phosphide semiconductors such as InGaP have refractive indices of about 3.6 to about 3.7 at 600 nm.

Electrodes 130 and 120 are, in one implementation, metal contacts formed from one or more layers of metals, including but not limited to gold, silver, nickel, aluminum, titanium, chromium, platinum, palladium, rhodium, rhenium, ruthenium, tungsten, and mixtures or alloys thereof. In another implementation, one or both of electrodes 130 and 120 are formed from transparent conductors such as indium tin oxide, zinc oxide, and oxidized metal alloys such as described by Song et al., “Formation of low resistance and transparent ohmic contacts to p-type GaN using Ni—Mg solid solution,” Applied Physics Letters, 83:(17):3513-3515 (2003).

The electrode 130 disposed between the extractor 140 (described below) and the n-p junction 114 an on the semiconductor layer 112 surface 116 is a patterned electrode. A planarizing layer 160 is disposed on the semiconductor layer 112 surface 116 and forms a coplanar light emitting surface 111 with the patterned electrode 130. At least a portion of the patterned electrode 130 extends beyond or outside the light emitting interface 145 to allow electrical coupling with an electrical source (not shown). Thus, the patterned electrode 130 in FIG. 1 extends out of the page further than the light emitting interface 145.

The patterned electrode 130 can have any useful configuration within the light emitting surface 111 and semiconductor layer 112. The patterned electrode 130 provides generally uniform current distribution to the n-p junction 114 while at the same time allowing a large fraction of the light emitting surface 111 to be unobstructed by a normally opaque electrode. The patterned electrode 130 can be defined by any useful pattern. Conventional electrode design rules and several useful electrode patterns are described in U.S. Pat. No. 6,307,218. Patterned electrode 130 can also function as a wire grid polarizer as described in co-pending patent application US2006/0091412. In an alternative embodiment, the patterned electrode 130 may include periodic or quasi-periodic microstructures such that surface plasmon polariton modes supported at the interface between the semiconductor layer and the metal patterned electrode are substantially scattered into light that propagates out of the plane of the semiconductor layer as described in U.S. Patent Publication No. 2005/0269578. For example the patterned electrode may include a square or triangular lattice of holes as described in US2006/0226429.

The patterned electrode 130 is electrically connected to one or more bonding pads 135 that remain exposed when the extractor is optically coupled to the light emitting surface. The bonding pads 135 are typically thicker than the patterned electrode and are suitable for wire bonding, e.g., ball bonding or wedge bonding, or for soldering, for attaching with a conducting medium. Manufacturing constraints generally dictate the size of the bonding pads 135, to be about ˜0.075×10⁻³ to 0.2×10⁻³ cm².

FIGS. 2A-2C are top views of the light emitting article shown in FIG. 1 and illustrate several useful electrode patterns including, for example, a spiral and an interdigitated pattern. General electrode design rules and further useful electrode patterns are described in U.S. Pat. No. 6,307,218. These views further illustrate that a portion of the patterned electrode 130 extends beyond the light emitting interface 145.

The planarizing layer 160 can be formed of any useful material that can be disposed about the patterned electrode 130 and having a refractive index equal to or greater than the refractive index of the semiconductor layer 112. Generally, the planarizing layer is substantially more transparent to the light emitted by the LED than the patterned electrode. The planarizing layer can be conducting or non-conducting. A partial listing of useful materials includes, for example Group III-V semiconductors, including but not limited to GaP, InGaP, GaAs, and GaN; Group II-VI semiconductors, including but not limited to ZnS, ZnSe, ZnTe, CdS, CdSe, and CdTe; Group IV semiconductors and compounds, including but not limited to Si, SiC, and Ge; organic semiconductors, metal and rare earth oxides, including but not limited to tungsten oxide, tellurium oxide, lead oxide, titanium oxide, nickel oxide, zirconium oxide, indium tin oxide, chromium oxide, antimony oxide, bismuth oxide, gallium oxide, germanium oxide, molybdenum oxide, cadmium oxide, cobalt oxide, cerium oxide, indium oxide, neodymium oxide; oxyhalides such as bismuth oxychloride; metal fluorides, including but not limited to magnesium fluoride and calcium fluoride; metals, including but not limited to Zn, In, Mg, and Sn; yttrium aluminum garnet (YAG), phosphide compounds, arsenide compounds, antimonide compounds, nitride compounds, high index organic compounds; and mixtures or alloys thereof.

The planarizing layer 160 can be formed by conventional deposition techniques such as, for example, spin coating, sputtering, evaporation, chemical vapor deposition, or as part of material growth by, for example, metal-organic chemical vapor deposition, vapor phase epitaxy, liquid phase epitaxy, or molecular beam epitaxy.

The extractor 140 is an optical element that is transparent and preferably has a high refractive index. Suitable materials for the extractor include, for example, inorganic materials such as high index glasses (e.g., Schott glass type LASF35, available from Schott North America, Inc., Elmsford, N.Y. under the trade name LASF35) and ceramics (e.g., sapphire, zinc oxide, zirconia, diamond, and silicon carbide). Sapphire, zinc oxide, diamond, and silicon carbide are particularly useful since these materials also have a relatively high thermal conductivity (0.2- 5.0 W/cm K). Other preferred glasses include novel aluminate and titanate glasses such as those described in U.S. patent application Ser. No. 11/381,518 (Leatherdale et al.), entitled LED EXTRACTOR COMPOSED OF HIGH INDEX GLASS. High index polymers or nanoparticle filled polymers are also contemplated. Suitable polymers can be thermosetting or thermoplastic. Thermoplastic polymers can include, for example, polycarbonate and cyclic olefin polymers. Thermosetting polymers can include, for example, acrylics, epoxy, silicones, etc. Suitable nanoparticles include zirconia, titania, zinc oxide, and zinc sulfide.

The extractor 140 is shown having a diverging form; however, the extractor 140 can have any useful shape such as, for example, diverging, converging (e.g., pyramidal), or other light-redirecting shape such as lens. Converging extractors are described, e.g., in U.S. patent application Ser. No. 11/381,324 (Leatherdale et al.), entitled LED PACKAGE WITH CONVERGING OPTICAL ELEMENT. Converging extractors have at least one converging side, a base, and an apex, the apex disposed at least partially over the base and having a surface area smaller than that of the base, and the at least one converging side converging from the base towards the apex. The shape of the converging extractor can be pyramidal, polyhedral, wedge-like, cone-like, etc., or some combination thereof. The base can have any shape, e.g., square, circular, symmetrical, non-symmetrical, regular, or irregular. The apex may be a point, a line, or a flat or rounded surface, and it resides over the base either centered or skewed away from the center of the base. For a converging extractor, the base is typically disposed adjacent and generally parallel to the LED die. Also, the base and the LED die may be substantially matched in size, or the base can be smaller or larger than the LED die. Diverging extractors are described, e.g., in U.S. Patent Publication No. 2006/0091784, entitled LED PACKAGE WITH NON-BONDED OPTICAL ELEMENT. A diverging extractor has at least one diverging side, an input surface, and an output surface that is larger than an input surface. Diverging extractors are generally shaped in the form of a taper. As for converging extractors, the input surface of a diverging extractor is typically disposed closest and generally parallel to the LED die. Also, the input surface and the LED die may be substantially matched in size, or the input surface can be smaller or larger than the LED die. Other examples of diverging extractors are described in U.S. Pat. No. 7,009,213 B2 and U.S. Pat. No. 6,679,621 B2.

The index of refraction of the extractor 140 (nₒ) is preferably similar to the index of the light emitting surface 111 (nₑ) In many embodiments, the difference between the two is no greater than 0.2 (|nₒ−nₑ|≦0.2). In some embodiments, the index of refraction of the extractor 140 (nₒ) is equal to the index of the light emitting surface 111 (nₑ).

Although the figures illustrate specific light emitting article structures, the present disclosure is independent of the structure and number of semiconductor layers in the light emitting article 100 and of the detailed structure of active region or n-p junction 114. Also, the light emitting article 100 can include, for example, transparent substrates and superstrates not illustrated in FIG. 1. Further, dimensions of the various elements of the light emitting article 100 illustrated in the various figures are not to scale.

FIG. 3 is a schematic cross-sectional side elevation view of an exemplary array of light emitting articles 200. The array of light emitting articles 200 includes a plurality of light emitting dies or diodes 210 optically coupled to a plurality of optical elements or extractors 240 forming an array and connected to each other by an array layer 250. The term “array” refers to a plurality of joined or interconnected articles.

As shown in FIG. 3, the array of light emitting dies or diodes 210 are connected by a common substrate such as, for example, a semiconductor wafer. The array of extractors 240 are connected by a common substrate such as, for example, a substrate layer 250. Forming a plurality of light emitting articles 200 by optically coupling an array of dies 210 with an array of extractors 240 offers a number of benefits such as, for example, ease of manufacture of a large number of light emitting articles 200.

The plurality of extractors 240 each include a light input surface 241 that is optically coupled to a corresponding light emitting surface 211 of the corresponding light emitting die or diode 210. Each interface between the light input surface 241 and the corresponding light emitting surface 211 is a light emitting interface 245.

Each light emitting die or diode 210 includes a plurality or stack of layers. The stack includes semiconductor layers and an active region capable of emitting light. Each light emitting die or diode 210 includes a first semiconductor layer 213, as described above, and a second semiconductor layer 212, as described above. Semiconductor layers 213 and 212 are electrically coupled to active region 214 or p-n junction 214, as described above. First contact or electrode 230 and second contact or electrode 220 are electrically coupled to semiconductor layers 212 and 213, respectively. A bonding pad 235 is in electrical contact with the patterned electrode 230 in a region of the light emitting surface 211 not covered by the extractor 240.

The electrode 230 disposed on the semiconductor layer 212 surface 216 and between the extractor 240 (described below) and the n-p junction 214 is a patterned electrode, as described above. A planarizing layer 260 is disposed on the semiconductor layer 212 surface 216 and forms a coplanar light emitting surface 211 with the patterned electrode 230, as described above.

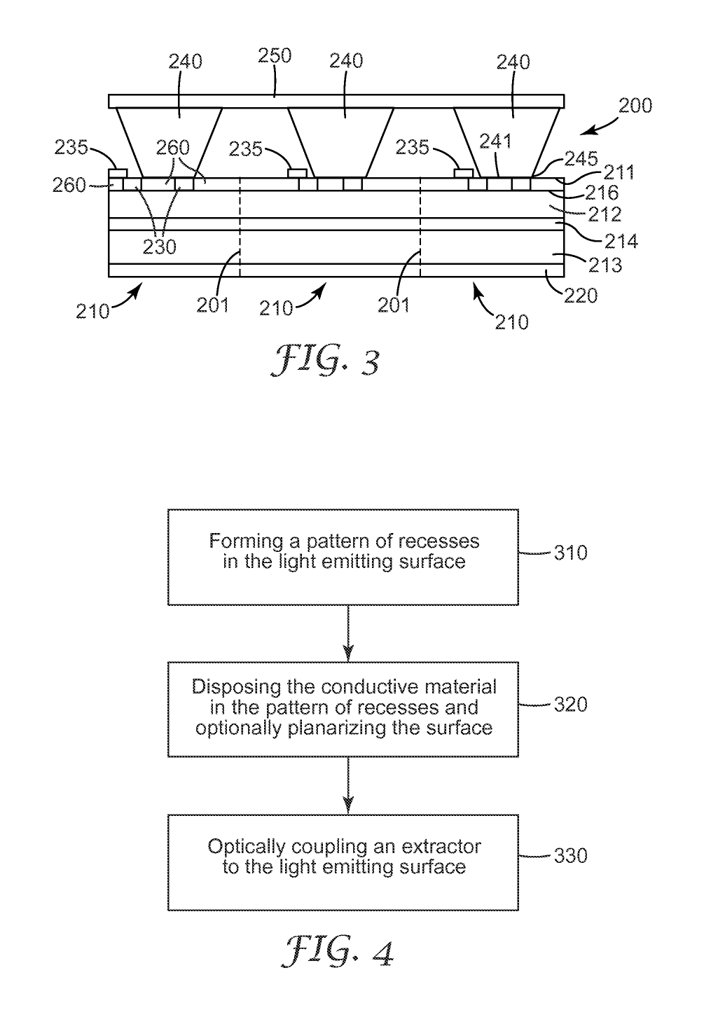

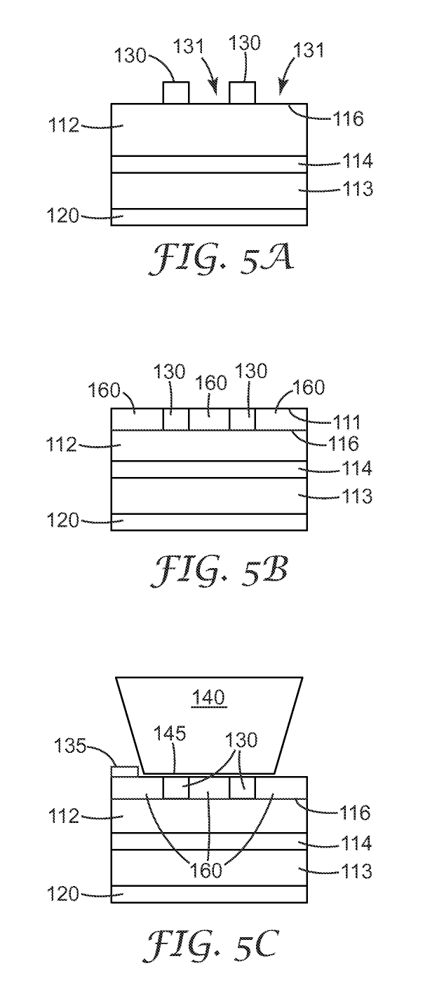

FIGS. 5A-5C are schematic cross-sectional side elevation views of a light emitting article made according to the steps shown in FIG. 4. Step 310 of FIG. 4 and the corresponding FIG. 5A show forming a patterned electrode 130 on the semiconductor layer 112 surface 116. The patterned electrode 130 projects away from the surface 116 and defines a plurality of voids 131. The light emitting die or diode 110 elements are described above in relation to FIG. 1.

The patterned electrode 130 can be formed by any useful method such as photolithography or nanoimprint lithography followed, for example, by electroless metal deposition, physical vapor deposition, chemical vapor deposition, metal plating, and combinations thereof. The patterned electrode 130 can be formed by one or more metal layers. In one embodiment, patterned electrode for III-nitride devices can include titanium under aluminum for an n-layer semiconductor, and palladium under aluminum under gold for a p-layer.

Step 320 of FIG. 4 and the corresponding FIG. 5B show disposing a planarizing layer on the semiconductor layer 112 surface 116 filling the voids 131 defined by the patterned electrode 130. The illustrated embodiment shows that the patterned electrode 130 and the light emitting surface 111 forms a coplanar surface where the patterned electrode 130 is substantially disposed within the semiconductor layer 112 and below the light emitting surface 111.

Once the voids 131 are filled with planarizing material, the light emitting surface 111 (planarizing layer 160) and/or the patterned electrode 130 can be planarized by any one or more combination of techniques. These techniques include, for example, chemical mechanical polishing, abrasive slurry polishing, and fixed abrasive polishing. These techniques provide a planarizing layer 160 light emitting surface 111 and/or the patterned electrode 130 having a roughness of less than 20 nm, as described above.

Step 330 of FIG. 4 and the corresponding FIG. 5C show optically coupling a light input surface 145 of an extractor 140 to the planarizing layer 160 light emitting surface 111. Optically coupling can be achieved in any useful manner, as described above.

An array of light emitting articles 200 can be formed as described above for forming a single light emitting article 100, by providing a plurality of light emitting dies or diodes 210 in wafer form, forming the plurality of patterned electrodes on the dies 210, disposing planarizing material on the dies, filling voids defined by the patterned electrodes to form the patterned electrodes 230, and planarizing the plurality of planarizing layer 260 light emitting surfaces 211 and optically coupling an array of extractors 240 to the array of dies 210, as described above. The array of light emitting articles 200 can optionally be singulated along area 201 by any useful method such as, for example, abrasive sawing, laser scribing, and wet or dry etching.

Illustrative embodiments of this disclosure are discussed and reference has been made to possible variations within the scope of this disclosure. These and other variations and modifications in the disclosure will be apparent to those skilled in the art without departing from the scope of the disclosure, and it should be understood that this disclosure is not limited to the illustrative embodiments set forth herein. Accordingly, the disclosure is to be limited only by the claims provided below.

1. A light emitting article comprising:
a light emitting diode comprising an n-layer or p-layer having a first refractive index value, a planarizing layer having a refractive index value equal to or greater than the first refractive index value and disposed on the n-layer or p-layer, and a patterned electrode disposed on the n-layer or p-layer; and
an extractor having a light input surface optically coupled to the planarizing layer forming a light emitting interface.

2. A light emitting article according to claim 1, wherein the planarizing layer and the patterned electrode form a coplanar surface.

3. A light emitting article according to claim 1, wherein the planarizing layer has a surface roughness of less than 20 nm.

4. A light emitting article according to claim 1, wherein the patterned electrode has an interdigitated pattern or spiral pattern.

5. A light emitting article according to claim 1, wherein at least a portion of the patterned electrode extends beyond the light emitting interface.

6. A light emitting article according to any of claims 1, further comprising a gap defined by the distance between the planarizing layer and the extractor, the gap being less than 100 nm.

7. A light emitting article according claim 1, further comprising an optically conducting bonding layer bonding the planarizing layer to the extractor.

8. A method of forming a light emitting article comprising:
providing a light emitting diode comprising an n-layer or p-layer having a first refractive index value, a planarizing layer having a refractive index value equal to or greater than the first refractive index value and disposed on the n-layer or p-layer, and a patterned electrode disposed on the n-layer or p-layer; and
optically coupling a light input surface of an extractor to the planarizing layer.

9. A method according to claim 8, wherein providing the light emitting diode further comprises forming the patterned electrode on the n-layer or p-layer, wherein the patterned electrode defines a plurality of voids.

10. A method according to claim 8, wherein providing the light emitting diode further comprises:
disposing the planarizing layer within the voids to form a filled patterned electrode; and
planarizing the filled patterned electrode to form a planarizing layer and patterned electrode coplanar surface.

11. A method according to claim 8, wherein the planarizing step forms a coplanar surface having a surface roughness of less than 20 nm.

12. A method according to claim 8, further comprising optically coupling a light input surface of an extractor to the planarizing layer and patterned electrode coplanar surface.

13. A method according to claim 8, wherein the optically coupling step comprises bonding the light input surface to the planarizing layer and patterned electrode coplanar surface with an optically conducting bonding layer.

14. An array of light emitting articles comprising:
a plurality of light emitting diodes, each light emitting diode comprising an n-layer or p-layer having a first refractive index value, a planarizing layer having a refractive index value equal to or greater than the first refractive index value and disposed on the n-layer or p-layer, and a patterned electrode disposed on the n-layer or p-layer; and
a plurality of extractors, each extractor having a light input surface optically coupled to the corresponding planarizing layer.

15. An array of light emitting articles according to claim 14, wherein at least selected planarizing layers and patterned electrodes form a coplanar surface.

16. A method of forming an array of light emitting articles comprising:
providing an array of light emitting diodes, wherein each light emitting diode comprises an n-layer or p-layer having a first refractive index value, a planarizing layer having a refractive index value equal to or greater than the first refractive index value and disposed on the n-layer or p-layer, and a patterned electrode disposed on the n-layer or p-layer; and
optically coupling an array of extractor light input surfaces to the array of light emitting diodes planarizing surfaces.

17. A method according to claim 16, wherein providing the array of light emitting diodes further comprises forming the patterned electrode on each n-layer or p-layer, wherein each patterned electrode defines a plurality of voids.

18. A method according to claim 17, wherein providing the array of light emitting diodes further comprises:
disposing the planarizing layer within the voids to form a plurality of filled patterned electrodes; and
planarizing each filled patterned electrode to form a planarizing layer and patterned electrode coplanar surface.

19. A method according to claim 18, wherein the planarizing step forms a plurality of coplanar surfaces having a surface roughness of less than 20 nm.

20. A method according to claim 16, wherein the providing step further comprises providing an array light emitting diodes in wafer form.

21. A method according to claim 18, further comprising singulating the array of light emitting articles to form a plurality of light emitting articles.

22. A method according to claim 18, wherein the optically coupling step comprises bonding the array of light emitting diodes to the array of extractor light input surfaces with an optically conducting bonding layer.
